(19) United States
(12) Patent Application Publication
(10) Pub. No.: US 2026/0301997 A1
(43) Pub. Date: Oct. 1, 2026

(54) PREPARATION METHOD FOR BRONZE-PROCESS NB3SN SUPERCONDUCTING WIRE, AND SUPERCONDUCTING WIRE

(71) Applicant: Xi'an Superconducting Wire Technologies Co., Ltd., XI'AN (CN)

(72) Inventors: Qiang GUO, XI'AN (CN); Ke ZHANG, XI'AN (CN); Bo WU, XI'AN (CN); Shuaiwei JU, XI'AN (CN); Tong CHEN, XI'AN (CN); Yuxin XUE, XI'AN (CN); Ruirui XIANG, XI'AN (CN); Guo YAN, XI'AN (CN); Xianghong LIU, XI'AN (CN); Yong FENG, XI'AN (CN); Jianfeng LI, XI'AN (CN); Pingxiang ZHANG, XI'AN (CN)

(73) Assignee: Xi'an Superconducting Wire Technologies Co., Ltd., XI'AN (CN)

(21) Appl. No.: 19/686,710

(22) Filed: May 24, 2026

Related U.S. Application Data
(63) Continuation of application No. PCT/CN2024/134110, filed on Nov. 25, 2024.

(30) Foreign Application Priority Data
Nov. 27, 2023 (CN) 202311585922.9

(51) Int. Cl. H01B 12/08

(52) U.S. Cl. CPC H01B 12/08

(57) ABSTRACT

Disclosed in the present application are a preparation method for a bronze-process Nb₃Sn superconducting wire, and a superconducting wire. The preparation method comprises: placing a bronze rod into an Nb tube, placing the Nb tube into a bronze tube, and performing rotary swaging, drawing and annealing to prepare a bronze/Nb single core rod; bundling up hundreds of bronze/Nb single core rods in a hexagonal close-packed arrangement and then coating the exterior with a barrier layer, and then placing the bronze/Nb single core rods into a copper tube to form a final billet; and heating the final billet and then sequentially performing extruding, drawing and intermediate annealing thereon, so as to obtain a bronze-process Nb₃Sn superconducting wire having ring-shaped filaments.

### CROSS-REFERENCE TO RELATED APPLICATION

This application is a continuation of a national phase entry under 35 U.S.C § 371 of International Application No. PCT/CN2024/134110, filed on Nov. 25, 2024, which claims priority to Chinese Parent Application No. 202311585922.9, titled “PREPARATION METHOD FOR BRONZE-PROCESS NB3SN SUPERCONDUCTING WIRE, AND SUPERCONDUCTING WIRE” and filed to the China National Intellectual Property Administration on Nov. 27, 2023, the entire contents of all of which are incorporated herein by reference.

### TECHNICAL FIELD

The present disclosure generally relates to the field of metal processing technologies, and especially relates to a preparation method for a bronze-process Nb₃Sn superconducting wire, and a superconducting wire.

### BACKGROUND

Bronze process Nb₃Sn superconducting wire is an important material for producing a high field magnet with a field strength greater than 10 T. The magnet that is produced needs to be firstly wound and then perform heat treatment to generate Nb₃Sn superconducting phase. A reaction between tin (Sn) and niobium (Nb) is a solid-state diffusion reaction, with a very slow speed.

At present, Nb filament mostly adopts a cylindrical structure, which has a limited contact area with the bronze matrix that is externally wrapped, thereby resulting in a long time for Sn and Nb to be fully reacted to form the Nb₃Sn superconducting phase.

### SUMMARY

An embodiment of the present disclosure provides a preparation method for a bronze-process Nb₃Sn superconducting wire, and a superconducting wire which can the problem that a long reaction time is occurred between the cylindrical Nb filament and the bronze matrix in the related art.

On one hand, an embodiment of the present disclosure provides a preparation method for a bronze-process Nb₃Sn superconducting wire, which includes:
placing a bronze rod into an Nb tube, then placing the Nb tube into a bronze tube, and performing rotary swaging, drawing and annealing to prepare a bronze/Nb single core rod;
bundling up a plurality of bronze/Nb single core rods in a hexagonal close-packed arrangement and then coating the exterior with a barrier layer, and then placing the assembly into a copper tube to form a final billet; and
sequentially performing extruding, drawing and annealing on the final billet, to obtain a bronze-process Nb₃Sn superconducting wire.

On the other hand, an embodiment of the present disclosure provides a bronze-process Nb₃Sn superconducting wire is prepared by the above preparation method.

The preparation method for the bronze-process Nb₃Sn superconducting wire, and the superconducting wire provided by the present disclosure has the following advantages:
the shape of the Nb filament is a circular ring-shaped, and the contact area between the bronze matrix and Nb is increased, which is conducive to the reaction between Sn and Nb during performing heat treatment, and a time of performing heat treatment can be shortened by more than 20%.

### BRIEF DESCRIPTION OF THE DRAWINGS

In order to more clearly understand the technical solution hereinafter in embodiments of the present disclosure or the related art, a brief description to the drawings used in detailed description of embodiments or the related art hereinafter is provided thereof. Obviously, the drawings described below are some embodiments of the present disclosure, for one of ordinary skill in the related art, other drawings can be obtained according to the drawings below on the premise of no creative work.

FIG. 1 is a schematic view of a bronze/Nb single core rod according to an embodiment of the present disclosure.

FIG. 2 is a schematic view of a superconducting wire according to an embodiment of the present disclosure.

The element labels according to the embodiment of the present disclosure shown as below:
1—bronze tube, 2—bronze rod, 3—Nb tube, 4—copper tube, 5—barrier layer, 6—bronze/Nb single core rod.

### DETAILED DESCRIPTION

Reference will now be made in detail to embodiments, examples of which are illustrated in the accompanying drawings. Obviously, the implementation embodiment in the description is a part of the present disclosure implementation examples, rather than the implementation of all embodiments, examples. According to the described exemplary embodiment of the present disclosure, all other embodiments obtained by one of ordinary skill in the related art on the premise of no creative work are within the protection scope of the present disclosure.

A preparation method for a bronze-process Nb₃Sn superconducting wire according to an embodiment of the present disclosure is provided. The preparation method includes the following steps.

Step S100, placing a bronze rod 2 into an Nb tube 3, placing the Nb tube 3 into a bronze tube 1, and performing rotary swaging, drawing and annealing to prepare a bronze/Nb single core rod 6.

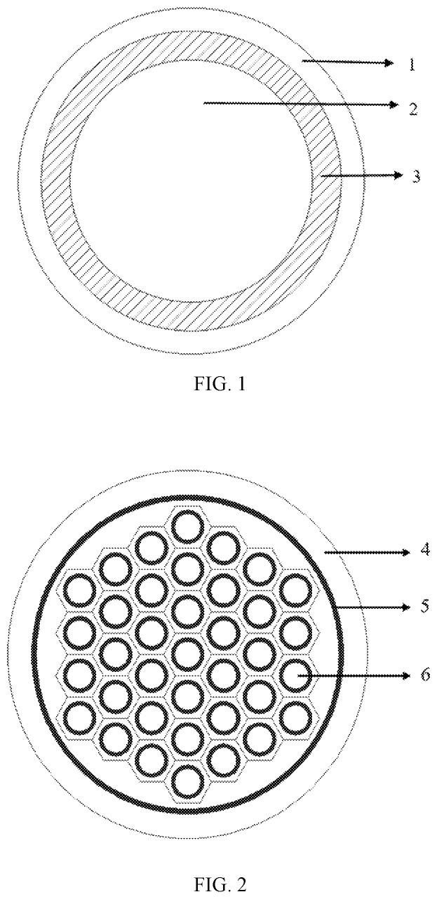

Illustratively, the outside of the Nb tube 3 is the bronze tube 1 and the bronze rod 2 is filled inside the Nb tube 3. The Nb tube 3 is made of Nb metal or Nb alloy, such as NbTi, NbTa, etc. The dimensional accuracy of the Nb tube 3 within ±0.03 mm, the surface roughness Ra is less than or equal to 0.8 μm, and the yield strength is more than 80 MPa. When processing the bronze tube 1 filled with the Nb tube 3, if the diameter of the bronze tube 1 is greater than or equal to 15 mm, rotary swaging is adopted with a deformation rate of not less than 30% per pass, and if the diameter of the bronze tube 1 is less than 15 mm, drawing is adopted with a deformation rate of not less than 30% per pass. In obtaining the bronze/Nb single core rod 6 with a circular Nb filament, a volume ratio of bronze to Nb is 1.0 to 5.0. A structure of the bronze/Nb single core rod 6 that is prepared is shown in FIG. 1.

Step S110, bundling up a plurality of bronze/Nb single core rods 6 in a hexagonal close-packed arrangement and then coating the exterior with a barrier layer 5, and then placing the assembly into a copper tube 4 to form a final billet.

Illustratively, the barrier layer 5 is made of Nb or Ta. In the final billet prepared, a ratio of the total radial cross-sectional areas of the bundled bronze/Nb single core rods 6 and the barrier layer 5 to the radial cross-sectional area of the copper tube 4 is 1.0 to 4.0.

Step S120, sequentially performing extruding, drawing and intermediate annealing on the final billet, to obtain the bronze-process Nb₃Sn superconducting wire.

A bronze-process Nb₃Sn superconducting wire according to an embodiment of the present disclosure is provided. The bronze-process Nb₃Sn superconducting wire is prepared by the above preparation method.

1. placing an Nb tube with a dimensional deviation of +0.03 mm, a surface roughness Ra of 0.8 μm, and a yield strength of 95 MPa into a bronze tube, and then placing a bronze rod into the Nb tube. When the diameter of the bronze tube is equal to or more than 15 mm, rotary swaging is performed with a single-pass deformation rate of 30%, followed by a drawing with a single deformation rate of 35%, to obtain a bronze/Nb single core rod with a ring-shaped Nb filament, wherein a volume ratio of bronze to Nb is 1.0.

2. bundling up hundreds of bronze/Nb single core rods in a hexagonal close-packed arrangement and then coating the exterior with a layer of a barrier layer Nb, and then fill into an oxygen free copper tube to obtain the final billet. A ratio of the total of cross-sectional areas of the bronze/Nb single core rods and the barrier layer Nb to a cross-sectional area of the oxygen free copper tube is 1.0. Heating the final billet and then sequentially performing extruding, drawing and annealing on the final billet, to obtain the bronze-process Nb₃Sn superconducting wire.

### Another Embodiment

A preparation method for a bronze-process Nb₃Sn superconducting wire of the present disclosure is provided. The preparation method includes the following steps:

1. placing a Nb2Ti tube with a dimensional deviation of +0.01 mm, a surface roughness Ra of 0.8 μm, and a yield strength of 83 MPa into a bronze tube, and then placing a bronze rod into a NbTi tube. When the diameter of the bronze tube is equal to or more than 15 mm, rotary swaging is performed with a single-pass deformation rate of 35%, followed by a drawing with a single deformation rate of 30%, to obtain a bronze/NbTi single core rod with a ring-shaped NbTi filament, wherein a volume ratio of bronze to NbTi is 3.0.

2. bundling up hundreds of bronze/NbTi single core rods in a hexagonal close-packed arrangement and then coating the exterior with a layer of a barrier layer Ta, and then fill into an oxygen free copper tube to obtain the final billet. A ratio of the total of cross-sectional areas of the bronze/NbTi single core rod and the barrier layer Ta to a cross-sectional area of the oxygen free copper tube is 2.0. Heating the final billet and then sequentially performing extruding, drawing and annealing on the final billet, to obtain the bronze-process Nb₃Sn superconducting wire.

### Another Embodiment

A preparation method for a bronze-process Nb₃Sn superconducting wire of the present disclosure is provided. The preparation method includes the following steps:

1. placing an Nb tube with a dimensional deviation of −0.03 mm, a surface roughness Ra of 0.8 μm, and a yield strength of 88 MPa into a bronze tube, and then placing a bronze rod into a Nb1.5Ta tube. When the diameter of the bronze tube is equal to or more than 15 mm, rotary swaging is performed with a single-pass deformation rate of 33%, followed by a drawing mode with a single deformation rate of 38%, to obtain a bronze/NbTa single core rod with a ring-shaped NbTa filament, wherein a volume ratio of bronze to NbTa is 5.0.

2. bundling up hundreds of bronze/NbTa single core rods in a hexagonal close-packed arrangement and then coating the exterior with a layer of a barrier layer Nb, and then fill into an oxygen free copper tube to obtain the final billet. A ratio of the total of cross-sectional areas of the bronze/NbTa single core rod and the barrier layer Nb to a cross-sectional area of the oxygen free copper tube is 4.0. Heating the final billet and then sequentially performing extruding, drawing and annealing on the final billet, to obtain the bronze-process Nb₃Sn superconducting wire.

### Verification Experiment

The bronze-process Nb₃Sn superconducting wires that are prepared by the preparation methods of the first embodiment to the third embodiment of the present disclosure above mentioned are compared with the Nb₃Sn superconducting wires that are not prepared by the preparation method of the present disclosure, the bronze-process Nb₃Sn superconducting wires that are prepared by the preparation methods of the first embodiment to the third embodiment of the present disclosure can be fully reacted to form the Nb₃Sn phase after being performed heat treatment at a temperature of 650° C. for 75 hours. In contrast, the Nb₃Sn superconducting wires that are not prepared by the preparation method of the present disclosure are performed heat treatment at a temperature of 650° C. for 100 hours, there is still a small amount of residue in the center of the Nb filament. It can be seen that the preparation method of the present disclosure can effectively shorten the time of heat treatment.

Although the preferred embodiments of the present disclosure have been described, any additional changes and modifications to these embodiments can made by one of ordinary skill in the related art once the basic inventive concept of the present disclosure is known. Therefore, the attached claims are intended to be interpreted as including preferred embodiments and all changes and modifications that fall within the protection scope of the present disclosure.

Obviously, one of ordinary skill in the related art can make various modifications and variations to the present disclosure without departing from the spirit and scope of the present disclosure. In this way, if these modifications and variations of the present disclosure fall within the scope of the appended claims and equivalent technologies of the present disclosure, then the present disclosure is also intended to include these modifications and variations.

1. A preparation method for a bronze-process Nb₃Sn superconducting wire, wherein, comprising:
placing a bronze rod (2) into an Nb tube (3), placing the Nb tube (3) into a bronze tube (1), and performing rotary swaging, drawing and annealing to prepare a bronze/Nb single core rod (6); bundling up a plurality of bronze/Nb single core rods (6) in a hexagonal close-packed arrangement and then coating the exterior with a barrier layer (5), and then placing the plurality of bronze/Nb single core rods into a copper tube (4) to form a final billet; and sequentially performing extruding, drawing and annealing on the final billet, to obtain a bronze-process Nb₃Sn superconducting wire; and
performing heat treatment on the bronze-process Nb₃Sn superconducting wire to enable Sn and Nb in the bronze/Nb single core rod (6) to be diffused, to form a Nb₃Sn phase.

2. The preparation method as claimed in claim 1, wherein in the bronze/Nb single core rod (6), a volume ratio of bronze to Nb is 1.0 to 5.0, and the Nb filament in the bronze/Nb single core rod (6) is ring-shaped.

3. The preparation method as claimed in claim 1, wherein the Nb tube (3) is made of Nb metal or Nb alloy, and a dimensional accuracy of the Nb tube (3) satisfies ±0.03 mm, a surface roughness Ra is less than or equal to 0.8 μm, and a yield strength is more than 80 MPa.

4. The preparation method as claimed in claim 1, wherein when processing the bronze tube (1) that is filled with the Nb tube (3), if a diameter of the bronze tube (1) is greater than or equal to 15 mm, rotary swaging is adopted with a deformation rate of not less than 30% per pass, and if the diameter of the bronze tube (1) is less than 15 mm, drawing is adopted with a deformation rate of not less than 30% per pass.

5. The preparation method as claimed in claim 1, wherein a ratio of a total of radial cross-sectional areas of the bronze/Nb single core rod (6) and the barrier layer (5) to a radial cross-sectional area of the copper tube (4) is 1.0 to 4.0.

6. A bronze-process Nb₃Sn superconducting wire, wherein the bronze-process Nb₃Sn superconducting wire is prepared by the preparation method as claimed in claim 1.

7. The bronze-process Nb₃Sn superconducting wire as claimed in claim 6, wherein in the bronze/Nb single core rod (6), a volume ratio of bronze to Nb is 1.0 to 5.0, and the Nb filament in the bronze/Nb single core rod (6) is ring-shaped.

8. The bronze-process Nb₃Sn superconducting wire as claimed in claim 6, wherein the Nb tube (3) is made of Nb metal or Nb alloy, and a dimensional accuracy of the Nb tube (3) satisfies ±0.03 mm, a surface roughness Ra is less than or equal to 0.8 μm, and a yield strength is more than 80 MPa.

9. The bronze-process Nb₃Sn superconducting wire as claimed in claim 6, wherein when processing the bronze tube (1) that is filled with the Nb tube (3), if a diameter of the bronze tube (1) is greater than or equal to 15 mm, rotary swaging is adopted with a deformation rate of not less than 30% per pass, and if the diameter of the bronze tube (1) is less than 15 mm, drawing is adopted with a deformation rate of not less than 30% per pass.

10. The bronze-process Nb₃Sn superconducting wire as claimed in claim 6, wherein a ratio of a total of radial cross-sectional areas of the bronze/Nb single core rod (6) and the barrier layer (5) to a radial cross-sectional area of the copper tube (4) is 1.0 to 4.0.
